(19) United States
(12) Patent Application Publication
(10) Pub. No.: US 2015/0176128 A1
(43) Pub. Date: Jun. 25, 2015

(54) Substrate Processing Apparatus

(71) Applicant: Eugene Technology Co., Ltd., Yongin-si (KR)

(72) Inventors: Byoung-Gyu Song, Yongin-si (KR); Kyong-Hun Kim, Yongin-si (KR); Yong-Ki Kim, Pyeongtaek-si (KR); Yang-Sik Shin, Yongin-si (KR); Chang-Dol Kim, Yongin-si (KR); Chang-Hun Shin, Icheon-si (KR); Eun-Duck Kim, Yongin-si (KR)

(21) Appl. No.: 14/573,644

(22) Filed: Dec. 17, 2014

(30) Foreign Application Priority Data
Dec. 20, 2013 (KR) 10-2013-0160434

(51) Int. Cl. C23C 16/46; C23C 16/455; C23C 16/458

(52) U.S. Cl. CPC C23C 16/46; C23C 16/458; C23C 16/455

(57) ABSTRACT

There is provided a substrate processing apparatus including: a chamber providing an internal space, in which a substrate is transferred through a passage and a process is performed on the substrate, and having a supply port supplying a gas to the substrate; and a susceptor installed in the internal space and including a heating region heating the substrate and a pre-heating region pre-heating the gas supplied from the supply port.

### CROSS-REFERENCE TO RELATED APPLICATION

This application claims the benefit of Korean Patent Application No. 10-2013-0160434 filed on Dec. 20, 2013, with the Korean Intellectual Property Office, the disclosure of which is incorporated herein by reference.

### BACKGROUND

1. Field of the Invention

The present disclosure relates to a substrate processing apparatus.

In general, in preparing semiconductor devices, efforts to improve apparatuses or processes for forming high-quality thin films on semiconductor substrates are continuing, and several methods have been commonly used to form thin films by utilizing surface reactions on semiconductor substrates.

Such methods include various types of chemical vapor deposition (CVD), including vacuum evaporation deposition, molecular beam epitaxy (MBE), low-pressure chemical vapor deposition, organometallic chemical vapor deposition, and plasma-enhanced chemical vapor deposition, as well as atomic layer epitaxy (ALE), and the like.

Meanwhile, technological developments aimed at improving productivity by increasing reactivity between a gas and a substrate at the time of forming thin films using the above methods while improving uniformity of the substrate have been in demand recently.

2. Description of Related Art

Korean Patent Laid-Open Publication No. 10-2010-0110822 is noted.

### SUMMARY OF THE INVENTION

An aspect of the present disclosure may provide a substrate processing apparatus which improves productivity and uniformity of a substrate.

An aspect of the present disclosure may also provide increased reactivity between a gas and a substrate by pre-heating the gas supplied to an internal space of a chamber.

According to an exemplary embodiment of the present disclosure, a substrate processing apparatus may include: a chamber providing an internal space, in which a substrate is transferred through a passage and a process is performed on the substrate, and having a supply port supplying a gas to the substrate; and a susceptor installed in the internal space and including a heating region heating the substrate and a pre-heating region pre-heating the gas supplied from the supply port.

A temperature of the pre-heating region may be higher than a temperature of the heating region.

A shape of the heating region may correspond to that of the substrate, and a length of the pre-heating region in a direction perpendicular to a direction of a gas flow may be greater than a diameter of the substrate.

A center of the heating region may be deviated from a center of the susceptor to be disposed nearer to the passage than to the supply port.

The susceptor may include a sub-susceptor having a rectangular parallelepiped shape, including an opening which is deviated from the center of the susceptor and providing the pre-heating region, and a main susceptor inserted into the opening and providing the heating region.

A coefficient of thermal expansion of the sub-susceptor may be lower than a coefficient of thermal expansion of the main susceptor.

The substrate processing apparatus may further include an exhaust port which is disposed in a portion of the chamber opposite to a portion thereof where the supply port is disposed, and which exhausts the gas having passed through the substrate.

The chamber may provide the internal space having a rectangular parallelepiped shape, and may have one side on which the passage is provided and the other side on which the supply port is provided.

The heating region may be disposed below the substrate, and the pre-heating region may be disposed between the heating region and the supply port.

The pre-heating region may be disposed between the heating region and the supply port to allow the gas to pass therethrough before the heating region.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a view schematically illustrating semiconductor manufacturing equipment according to an exemplary embodiment of the present disclosure;

FIG. 2 is a view schematically illustrating the substrate processing apparatus illustrated in FIG. 1;

FIG. 3 is an exploded perspective view of the substrate processing apparatus illustrated in FIG. 2;

FIGS. 4 and 5 are views illustrating a stand-by position and a processing position of an exhaust part illustrated in FIG. 2;

FIG. 6 is a view illustrating a heating region and a pre-heating region of a susceptor illustrated in FIG. 2;

FIG. 7 is a modified example of the heating region and the pre-heating region illustrated in FIG. 6; and

FIG. 8 is a view illustrating a gas flow in the susceptor illustrated in FIG. 6.

### DETAILED DESCRIPTION OF THE INVENTION

Hereinafter, exemplary embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

Concerning reference numerals in the drawings attached to enhance comprehension of the present disclosure, the same or similar numbers are designated for components relevant to the same function in each exemplary embodiment. Meanwhile, a processing apparatus according to exemplary embodiments of the present disclosure will be described to be used for processing a substrate W by way of example, but may be used for processing various types of objects.

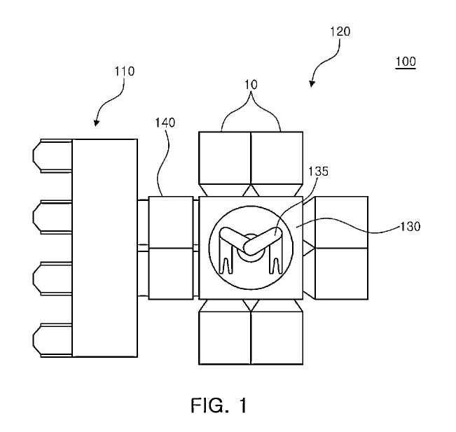

FIG. 1 is a view schematically illustrating semiconductor manufacturing equipment according to an exemplary embodiment of the present disclosure. As illustrated in FIG. 1, generally, semiconductor manufacturing equipment 100 may include processing equipment 120 and an equipment front end module (EFEM) 110. The equipment front end module 110 may be installed in the front of the processing equipment 120 and may transfer substrates W between substrate containers and the processing equipment.

The substrate W may go through several processes inside the processing equipment 120. The processing equipment 120 may include a transfer chamber 130, a loadlock chamber 140, and a plurality of substrate processing apparatuses 10. The transfer chamber 130 may have a mostly polygonal shape when viewed from above, and the loadlock chamber 140 and the plurality of substrate processing apparatuses 10 may be installed on sides of the transfer chamber 130. The transfer chamber 130 may have a quadrilateral shape, and two of the substrate processing apparatuses 10 may be installed on each side of the transfer chamber 130, except on a side of the transfer chamber 130 on which the loadlock chamber 140 is installed.

The loadlock chamber 140 may be positioned on the side of the transfer chamber 130 adjacent to the equipment front end module 110. After the substrate W remains in the loadlock chamber 140 temporarily, it may be loaded onto the processing equipment 120 and be processed therein. After the substrate W is completely processed, it may be unloaded from the processing equipment 120 and remain in the loadlock chamber 140 temporarily. The transfer chamber 130 and each of the plurality of substrate processing apparatuses 10 may be maintained in a vacuum state, and the loadlock chamber 140 may have a vacuum or atmospheric pressure existing therein. The loadlock chamber 140 may prevent external contaminants from flowing into the transfer chamber 130 and the plurality of substrate processing apparatuses 10, and prevent the growth of an oxide layer on a surface of the substrate W by blocking exposure of the substrate W to air while the substrate W is being transferred.

A gate valve (not shown) may be installed between the loadlock chamber 140 and the transfer chamber 130, as well as between the loadlock chamber 140 and the equipment front end module 110, and the transfer chamber 130 may contain a substrate handler 135 (a transfer robot). The substrate handler 135 may transfer the substrate W between the loadlock chamber 140 and each of the plurality of substrate processing apparatuses 10. For example, the substrate handler 135 inside the transfer chamber 130 may load the substrates W simultaneously onto the substrate processing apparatuses 10 disposed on the sides of the transfer chamber 130 by using first and second blades.

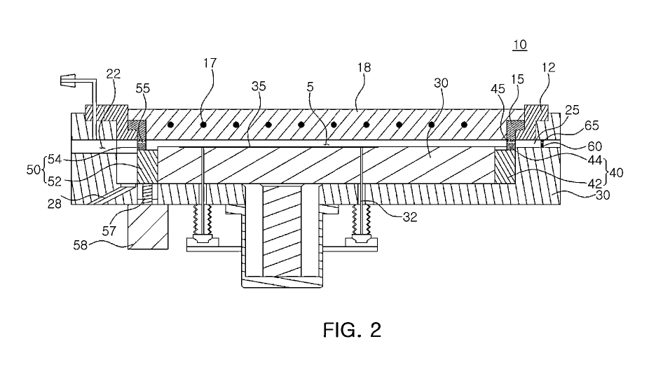

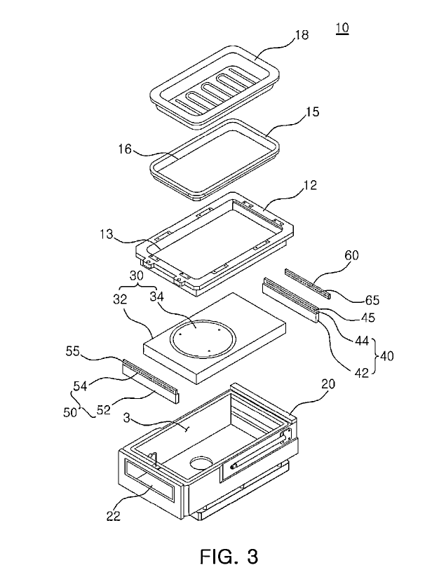

FIG. 2 is a view schematically illustrating the substrate processing apparatus illustrated in FIG. 1, and FIG. 3 is an exploded perspective view of the substrate processing apparatus illustrated in FIG. 2. As illustrated in FIGS. 2 and 3, the substrate W may be transferred into a chamber 20, in which a process may be performed on the substrate W, through a passage 22 which is formed on one side of the chamber 20. The chamber 20 may have an open top, and a chamber cover 12 may be installed on the open top of the chamber 20. The chamber cover 12 may include a first installation groove 13, and an insulator 15 may be inserted into the first installation groove 13. The insulator 15 may include a second installation groove 16, and a top electrode 18 may be installed into the second installation groove 16 and may form a plasma in an internal space 3 of the chamber 20.

A bottom surface of the top electrode 18 may be parallel to a top surface of a susceptor 30, and a high-frequency current from the outside may be supplied through antennas 17 installed inside the top electrode 18. The chamber cover 12, the insulator 15, and the top electrode 18 may close the open top of the chamber 20, and create the internal space 3. The chamber cover 12 may be connected to the chamber 20 by a hinge, allowing the top of the chamber 20 to open up during a repair in the chamber 20.

The chamber 20 may include the internal space 3, in which the process may be performed on the substrate W, and the internal space 3 may have a rectangular parallelepiped shape. The susceptor 30 may be installed in the internal space 3, and may be disposed below the substrate W to heat the substrate W. The susceptor 30 may have a rectangular parallelepiped shape corresponding to that of the internal space 3, and may include a sub-susceptor 32 having an opening (not shown) therein and a main susceptor 34 being insertable in the opening.

On a side opposite to the passage 22 inside the chamber 20, one or more supply ports 25 may be formed to supply a gas to the inside of the chamber 20. A diffuser part 40 may be installed between the susceptor 30 and inner walls of the chamber 20. The diffuser part 40 may include a plurality of diffuser holes 45 disposed in front of the supply port 25 and diffuser the gas supplied through the supply port 25.

The diffuser part 40 may include a diffuser body 42 and a diffuser plate 44. The diffuser body 42 may fill a space between the susceptor 30 and the inner walls of the chamber 20, and contact a side surface of the susceptor 30 and the inner walls of the chamber 20. The diffuser plate 44 maybe protruded from a top surface of the diffuser body 42 to be disposed outside the diffuser body 42 and may contact a bottom surface of the insulator 15. The diffuser holes 45 may be formed in the diffuser plate 44.

Also, on a side opposite to the supply port 25 inside the chamber 20, one or more exhaust ports 28 may be formed to exhaust an unreacted gas, a reaction by-product, and the like, having passed through the substrate W. An exhaust part 50 may be installed to ascend and descend between the susceptor 30 and an inner wall of the chamber 20 in which the passage 22 is formed. The exhaust part 50 may include a plurality of exhaust holes 55 exhausting the gas having passed through the substrate W while maintaining a flow of the gas. The diffuser part 40 and the exhaust part 50 may be symmetrical with respect to each other, and the diffuser holes 45 and the exhaust holes 55 may be formed in parallel with each other.

The exhaust part 50 may include an exhaust body 52 and an exhaust plate 54. The exhaust body 52 may be installed in a space between the susceptor 30 and the inner walls of the chamber 20, and may contact a side surface of the susceptor 30 while being spaced apart from the inner wall of the chamber 20. An inlet (or top portion) of the exhaust port 28 may be disposed on a bottom surface of the space between the exhaust body 52 and the chamber 20.

For example, a cylinder rod 57 may be connected to a bottom surface of the exhaust part 50, and may ascend and descend along with the exhaust part 50 by a cylinder 58. The exhaust part 50 and the diffuser part 40 may be symmetrical with respect to each other. The exhaust holes 55 and the diffuser holes 45 may be formed in a plurality in top portions of the exhaust plate 54 and the diffuser place 44, respectively. The plurality of exhaust holes 55 may have pre-determined intervals therebetween, and the plurality of diffuser holes 45 may have pre-determined intervals therebetween. The exhaust holes 55 and the diffuser holes 45 may be of a round or elongated shape.

The diffuser part 40 and the exhaust part 50 may each fill the space between the susceptor 30 and the inner walls of the chamber 20. The top of the chamber 20 may be closed by the chamber cover 12, the insulator 15, and the top electrode 18, which serve to block the internal space 3 and form a reaction space 5, in which the gas and the substrate W may react.

In this case, the diffuser part 40 and the exhaust part 50 may be disposed perpendicular to the two inner walls of the chamber 20 adjacent thereto, and the other two inner walls of the chamber 20 in a length direction thereof may be disposed parallel to a direction of the gas flow; thus the reaction space 5 may have a rectangular parallelepiped shape. Also, the exhaust part 50 may be disposed in a portion of the chamber in which the passage 22 is disposed, so that asymmetry in the reaction space 5 caused by the passage 22 may be eliminated and non-uniformity occurring due to presence of the passage 22 may be prevented.

In other words, the passage 22 may be formed on one side of the chamber 20, allowing the substrate W to be loaded into and unloaded out of the chamber 20 through the passage 22. However, a presence of the passage 22 inevitably causes asymmetry in the internal space of the chamber 20. On the other hand, blocking the passage 22 from the reaction space 5 using the exhaust plate 54 may provide symmetry to the reaction space 5.

That is, the gas may be supplied through the supply port 25 to the reaction space 5 in the chamber 20 and diffused by passing through the diffuser holes 45 formed in the diffuser plate 44. The diffused gas may pass through the substrate W in the reaction space 5, and the unreacted gas and the reaction by-products maybe exhausted through the exhaust holes 55 formed in the exhaust plate 54 and the exhaust port 28. Therefore, a laminar flow of the gas may be maintained through the exhaust holes 55 and the diffuser holes 45, formed in the exhaust plate 54 and the diffuser plate 44, respectively, and a uniform supply of the gas may be provided throughout the entire surface of the substrate W.

In this case, the top surface of the diffuser body 42 may be lower than the top surface of the susceptor 30, thus a height of the reaction space 5 above the diffuser body 42 may be greater than a height of the reaction space 5 above the susceptor 30. Thus, the gas, having passed through the diffuser holes 45, may be diffused in the reaction space 5 above the diffusion body 42. Likewise, a top surface of the exhaust body 52 may be lower than the top surface of the susceptor 30, thus a height of the reaction space 5 above the exhaust body 52 may be greater than a height of the reaction space 5 above the susceptor 30. Thus, the gas, having passed through the top of the susceptor 30, may flow uniformly in the reaction space above the exhaust body 52. Therefore, the gas, supplied through the diffuser part 40 and exhausted through the exhaust part 50, may have a uniform flow in the reaction space 5 in the length direction of the diffuser part 40 and the exhaust part 50, regardless of a location of the gas in the entire reaction space 5.

Also, a sub-diffuser plate 60 may be installed in the supply port 25. The sub-diffuser plate 60 and the diffuser plate 44 may be spaced apart from each other at a pre-determined distance, and the sub-diffuser plate 60 may include a plurality of sub-diffuser holes 65, as in the diffuser plate 44. The sub-diffuser holes 65 and the diffuser holes 45 may be formed alternately with each other, such that the gas, having passed through the sub-diffuser holes 65, may be diffused again through the diffuser holes 45, thus forming a uniform laminar flow on the surface of the substrate W, whereby a uniform gas supply may be achieved.

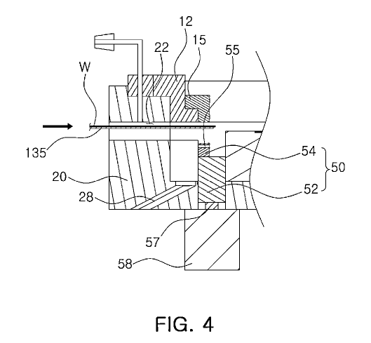

FIGS. 4 and 5 are views illustrating a stand-by position and a processing position of the exhaust part illustrated in FIG. 2. The cylinder rod 57 may be connected to the bottom surface of the exhaust part 50, and may ascend and descend by the cylinder 58. As illustrated in FIG. 4, the exhaust part 50 may be disposed further in the chamber 20 than the passage 22 may be disposed. When the substrate W is loaded onto the inside of the chamber 20, the cylinder rod 57 may descend along with the exhaust part 50, in a “stand-by position”, to provide a transfer passage for the substrate W.

Moreover, as illustrated in FIG. 5, after the substrate W is loaded, when the processes are performed on the substrate W, a gate valve disposed outside the passage 22 may be closed, and the cylinder 58 may ascend along with the exhaust part 50, in a “processing position”. Therefore, during the processes of the substrate W, the sub-diffuser plate 60, the diffuser plate 44, and the exhaust plate 54 may be disposed at substantially the same height, and the gas diffused through the sub-diffuser plate 60 and the diffuser plate 44 may pass through the substrate W and maintain the laminar flow up to the exhaust plate 54.

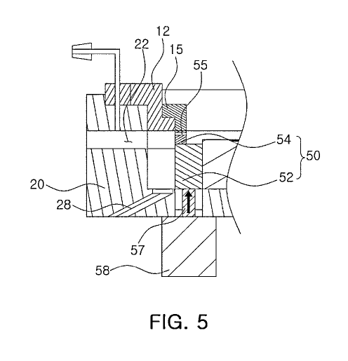

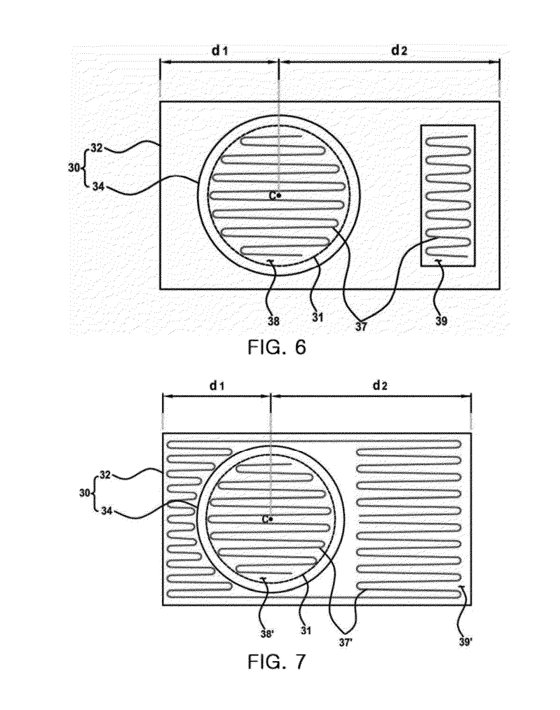

FIG. 6 is a view illustrating a heating region and a pre-heating region of the susceptor illustrated in FIG. 2, and FIG. 7 is a modified example of the heating region and the pre-heating region illustrated in FIG. 6. As illustrated in FIG. 6, the susceptor 30 may include a heating region 38 heating the substrate W and a pre-heating region 39 pre-heating the gas introduced through the supply port 25. The heating region 38 may correspond to a recess 31 in which the substrate W may be seated. The heating region 38 may include a heater (a heating wire) 37, and the heating region 38 may be disposed nearer to the passage 22 than to the supply port 25.

In other words, a distance d₁ between a center C of the heating region 38 and the passage 22 is less than a distance d₂ between the center C of the heating region 38 and the supply port 25. By disposing the heating region 38 nearer to the passage 22 than to the supply port 25, the gas supplied through the supply port 25 may pass through the sub-diffuser holes 65 and the diffuser holes 45 in sequence, whereby a distance and a time sufficient for forming a laminar flow with respect to the substrate W may be secured.

Meanwhile, as illustrated in FIG. 7, a pre-heating region 39′ may be formed on the entire surface of the susceptor 30 excluding a heating region 38′. That is, the sub-susceptor 32 may include the pre-heating region 39′, and the main susceptor 34 may include the heating region 38′. The sub-susceptor 32 and the main susceptor 34 may each include a heater (a heating wire) 37′, and a temperature of the sub-susceptor 32 may be higher than that of the main susceptor 34.

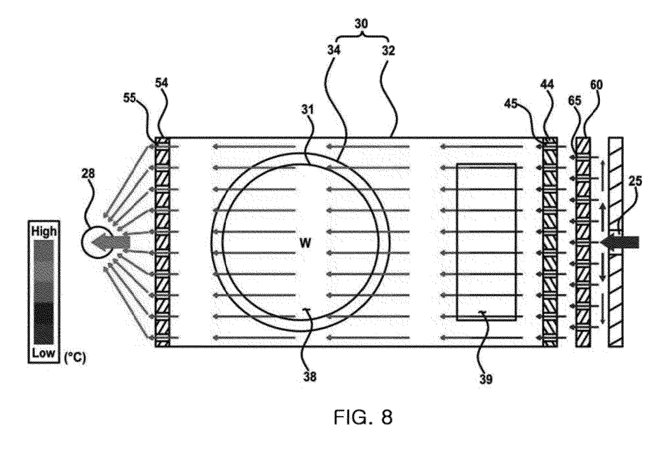

FIG. 8 is a view illustrating the gas flow in the susceptor illustrated in FIG. 6. As illustrated in FIG. 8, the sub-diffuser holes 65 and the diffuser holes 45 may be formed alternately with each other and the gas supplied through the supply port 25 may be diffused through the sub-diffuser holes 65 and be then diffused again through the diffuser holes 45. Thus, the gas may form the laminar flow above the surface of the substrate W, whereby the uniform gas supply may be provided. Furthermore, while maintaining the laminar flow, the gas may be exhausted through the exhaust holes 55 formed in the exhaust plate 54. Thus, the gas may uniformly flow throughout central and edge portions of the substrate W.

The reaction space 5 may have a rectangular parallelepiped shape, and thus may maintain a same distance from the diffuser plate 44 to the exhaust plate 54, thereby enabling the gas to maintain a uniform flow from the diffuser plate 44 to the exhaust plate 54 in the reaction space 5. On the other hand, in a case in which the reaction space 5 has a circular shape, a distance from the diffuser plate 44 to the exhaust plate 54 changes depending on a location of the gas in the reaction space 5, causing difficulty for the gas to maintain a laminar flow in the reaction space 5.

The pre-heating region 39 may be disposed between the heating region 38 and the supply port 25, and the pre-heating region 39 may include a heater 37 as in the heating region 38. The heating region 38 and the pre-heating region 39 may be controlled separately, for example, a temperature of the pre-heating region 39 may be higher than that of the heating region 38. The center C of the heating region 38 may be deviated from the center of the susceptor 30 so as to be disposed nearer to the passage 22 than to the supply port 25. The gas pre-heated in the pre-heating region 39 may flow toward the substrate W.

As described above, the susceptor 30 may include the sub-susceptor 32 and the main susceptor 34. The main susceptor 34 may provide the heating region 38, and the sub-susceptor 32 may provide the pre-heating region 39. The sub-susceptor 32 may include the opening which is disposed to be deviated from the center of the susceptor 30 and may have a rectangular parallelepiped shape corresponding to that of the internal space 3. The main susceptor 34 may be inserted into the opening formed in the sub-susceptor 32 and may have a shape corresponding to that of the substrate W. A length of the pre-heating region 39 in a direction perpendicular to a direction of the gas flow may be greater than a diameter of the substrate W, and thus, the gas flowing through the supply port 25 into the reaction space 5 may pass through the pre-heating region 39 and flow toward the substrate W, while having an increased temperature.

Meanwhile, the sub-susceptor 32 may be formed of a material having a lower coefficient of thermal expansion than that of the main susceptor 34. For example, the sub-susceptor 32 may be formed of aluminum nitride (AlN: coefficient of thermal expansion=4.5⁻⁶/° C.) and the main susceptor 34 may be formed of aluminum (Al: coefficient of thermal expansion=23.8⁻⁶/° C.). Therefore, the pre-heating region 39 of the sub-susceptor 34 may prevent damages to the substrate W caused by a heat expansion occurring at the time of heating the substrate W at a temperature higher than that of the heating region 38 formed in the main susceptor 32.

Therefore, a limitation regarding increased amounts of a gas and costs used in substrate processing, which result from an increased volume of internal space of a chamber by disposing an exhaust port to be spaced apart from a substrate in order to eliminate a non-uniformity of the gas in existing substrate processing apparatuses and a limitation regarding a longer processing time needed to perform a deposition on the substrate may be compensated for in the substrate processing apparatus according to the exemplary embodiments of the present disclosure. Moreover, substrate processing efficiency and quality may be improved by forming the laminar flow of the gas in the internal space 3 of the chamber 20 and by minimizing the space needed for the gas flow, through utilizing the diffuser part 40, the sub-diffuser plate 60, and the exhaust part 50.

Also, reactivity between the gas and the substrate W may be improved by pre-heating the gas introduced from the supply port 25 through the pre-heating region 39 providing a temperature higher than that of the heating region 38, and by having the pre-heated gas flow toward the substrate W and rapidly obtaining a processing temperature in the heating region 38.

While exemplary embodiments have been shown and described above, it will be apparent to those skilled in the art that modifications and variations could be made without departing from the scope of the present invention as defined by the appended claims.

What is claimed is:

1. A substrate processing apparatus, comprising:
a chamber providing an internal space, in which a substrate is transferred through a passage and a process is performed on the substrate, and having a supply port supplying a gas to the substrate; and
a susceptor installed in the internal space and including a heating region heating the substrate and a pre-heating region pre-heating the gas supplied from the supply port.

2. The substrate processing apparatus of claim 1, wherein a temperature of the pre-heating region is higher than a temperature of the heating region.

3. The substrate processing apparatus of claim 1, wherein a shape of the heating region corresponds to that of the substrate, and
a length of the pre-heating region in a direction perpendicular to a direction of a gas flow is greater than a diameter of the substrate.

4. The substrate processing apparatus of claim 1, wherein a center of the heating region is deviated from a center of the susceptor to be disposed nearer to the passage than to the supply port.

5. The substrate processing apparatus of claim 1, wherein the susceptor includes:
a sub-susceptor having a rectangular parallelepiped shape, including an opening which is deviated from the center of the susceptor, and providing the pre-heating region; and
a main susceptor inserted into the opening and providing the heating region.

6. The substrate processing apparatus of claim 5, wherein a coefficient of thermal expansion of the sub-susceptor is lower than a coefficient of thermal expansion of the main susceptor.

7. The substrate processing apparatus of claim 1, further comprising an exhaust port which is disposed in a portion of the chamber opposite to a portion thereof where the supply port is disposed, and which exhausts the gas having passed through the substrate.

8. The substrate processing apparatus of claim 1, wherein the chamber provides the internal space having a rectangular parallelepiped shape, and has one side on which the passage is provided and the other side on which the supply port is provided.

9. The substrate processing apparatus of claim 1, wherein the heating region is disposed below the substrate, and
the pre-heating region is disposed between the heating region and the supply port.

10. The substrate processing apparatus of claim 9, wherein the pre-heating region is disposed between the heating region and the supply port to allow the gas to pass therethrough before the heating region.
